(19) United States
(12) Patent Application Publication
(10) Pub. No.: US 2025/0105126 A1
(43) Pub. Date: Mar. 27, 2025

(54) DISPLAY DEVICE AND MOBILE ELECTRONIC DEVICE INCLUDING THE SAME

(71) Applicant: Samsung Display Co., LTD., Yongin-si (KR)

(72) Inventors: Woo Jung JUNG, Yongin-si (KR); Won Tae KIM, Yongin-si (KR)

(73) Assignee: Samsung Display Co., LTD., Yongin-si (KR)

(21) Appl. No.: 18/640,300

(22) Filed: Apr. 19, 2024

(30) Foreign Application Priority Data
Sep. 27, 2023 (KR) 10-2023-0131133

(51) Int. Cl. H01L 23/498; H01L 25/18; H10K 59/90

(52) U.S. Cl. CPC H01L 23/49838; H01L 23/4985; H01L 25/18; H10K 59/90

(57) ABSTRACT

According to an embodiment, a display device may include a display panel, a plurality of flexible films attached to a side of the display panel, and a circuit board electrically connected to the display panel through the flexible films. Each of the flexible films may include a first display driver IC (DDI) and a second DDI spaced apart from each other on a surface of the flexible film, a first common line electrically connecting an input pad and the first DDI, a second common line branching from the first common line and extending under the first DDI to bypass the first DDI, a third common line electrically connecting the second common line and the second DDI, a first independent line electrically connecting the input pad and the first DDI, and a second independent line electrically connecting the input pad and the second DDI.

### CROSS-REFERENCE TO RELATED APPLICATIONS

This application claims priority under 35 U.S.C. § 119 from Korean Patent Application No. 10-2023-0131133 filed on Sep. 27, 2023 in the Korean Intellectual Property Office, the entire contents of which are incorporated herein by reference.

### BACKGROUND

### 1. Technical Field

The disclosure relates to a display device and a mobile electronic device including the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions.

Display devices are increasingly equipped with display panels with high resolution and high pixels per inch (PPI) specifications according to user demand. Accordingly, research and development are being conducted on driving circuits for driving display panels. For example, chip on film (COF) package technology having a multi-chip structure has been proposed for display panels of about 200 PPI or more. The COF package technology having the multi-chip structure places multiple integrated circuit (ICs) on a flexible film to place many driver ICs in a limited space (panel width).

However, the COF package technology having the multi-chip structure has difficulty in securing a pad pitch, thus resulting in high process difficulty and reduced yield and reliability.

### SUMMARY

Aspects of the disclosure provide a display device which can increase yield and reliability by readily securing a pad pitch while placing multiple integrated circuits on a flexible film and a mobile electronic device including the display device.

According to an embodiment of the disclosure, a display device may include a display panel, a plurality of flexible films attached to a side of the display panel, and a circuit board electrically connected to the display panel through the plurality of flexible films. Each of the plurality of flexible films may include a first display driver IC (DDI) and a second DDI spaced apart from each other on a surface of the flexible film, a first common line electrically connecting an input pad and the first DDI, a second common line branching from the first common line and extending under the first DDI to bypass the first DDI, a third common line electrically connecting the second common line and the second DDI, a first independent line electrically connecting the input pad and the first DDI, and a second independent line electrically connecting the input pad and the second DDI.

Each of the plurality of flexible films may include a first metal layer adjacent to a front surface of the flexible film and a second metal layer adjacent to a rear surface of the flexible film, and the first DDI and the second DDI may be disposed on the front surface of the flexible film.

In each of the plurality of flexible films, the input pad may be disposed adjacent to a side of the flexible film and may be disposed on the front surface of the flexible film, an output pad may be disposed adjacent to another side of the flexible film and may be disposed on the rear surface of the flexible film, and the first DDI may be disposed between the input pad and the second DDI.

In each of the plurality of flexible films, the first common line and the third common line may be disposed in the first metal layer, and the second common line may be disposed in the second metal layer.

In each of the plurality of flexible films, the first common line and the third common line may be electrically connected through a plurality of through holes penetrating portions of the flexible film to connect the first metal layer and the second metal layer.

In each of the plurality of flexible films, the plurality of through holes may include a first through hole in which the first common line and an end of the second common line are electrically connected, and a second through hole in which the third common line and another end of the second common line are electrically connected.

In each of the plurality of flexible films, the first independent line may be electrically connected to the first DDI through the first metal layer.

In each of the plurality of flexible films, the second independent line may be electrically connected to the second DDI through the first metal layer and the second metal layer.

Each of the plurality of flexible films may include a plurality of bypass lines disposed on opposing front and rear surfaces of the flexible film to bypass the first DDI and the second DDI.

In each of the plurality of flexible films, the first DDI may drive a plurality of first subpixels disposed in a first display area of the display panel, the second DDI may drive a plurality of second subpixels disposed in a second display area adjacent to the first display area, and a circuit included in the first DDI and a circuit included in the second DDI may be the same.

Each of the plurality of flexible films may include a first metal layer adjacent to a front surface of the flexible film, wherein the first DDI and the second DDI may be disposed on the front surface of the flexible film.

In each of the plurality of flexible films, the input pad may be disposed adjacent to a side of the flexible film and may be disposed on the front surface of the flexible film, an output pad may be disposed adjacent to another side of the flexible film and may be disposed on a rear surface of the flexible film, and the first DDI may be disposed between the input pad and the second DDI.

The first through third common lines and the first and second independent lines in each of the plurality of flexible films may be disposed in the first metal layer.

The second common line in each of the plurality of flexible films may pass between a plurality of bumps of the first DDI attached to the front surface of the flexible film.

The second independent line in each of the plurality of flexible films may pass between a plurality of bumps of the first DDI attached to the front surface of the flexible film.

According to an embodiment of the disclosure, a mobile electronic device may include a display panel, a plurality of flexible films attached to a side of the display panel, and a circuit board electrically connected to the display panel through the plurality of flexible films. Each of the plurality of flexible films may include a first DDI and a second DDI spaced apart from each other on a surface of the flexible film, a first common line electrically connecting an input pad and the first DDI, a second common line branching from the first common line and extending under the first DDI to bypass the first DDI, a third common line electrically connecting the second common line and the second DDI, a first independent line electrically connecting the input pad and the first DDI, and a second independent line electrically connecting the input pad and the second DDI.

Each of the plurality of flexible films may include a first metal layer adjacent to a front surface of the flexible film and a second metal layer adjacent to a rear surface of the flexible film, and the first DDI and the second DDI may be disposed on the front surface of the flexible film.

In each of the plurality of flexible films, the input pad may be disposed adjacent to a side of the flexible film and may be disposed on the front surface of the flexible film, an output pad may be disposed adjacent to another side of the flexible film and may be disposed on the rear surface of the flexible film, and the first DDI may be disposed between the input pad and the second DDI.

In each of the plurality of flexible films, the first common line and the third common line may be disposed in the first metal layer, and the second common line may be disposed in the second metal layer.

Each of the plurality of flexible films may be penetrated by a plurality of through holes in which the first common line and the third common line may be electrically connected and in which the first metal layer and the second metal layer may be electrically connected.

However, aspects of the disclosure may not be restricted to the one set forth herein. The above and other aspects of the disclosure will become more apparent to one of ordinary skill in the art to which the disclosure pertains by referencing the detailed description of the disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is an exploded perspective view of a display device according to an embodiment;

FIG. 2 is a bottom view illustrating an example of a display panel in case that flexible films in FIG. 1 are unfolded;

FIG. 3 is a bottom view illustrating an example of the display panel to which a bottom chassis is coupled in case that the flexible films in FIG. 1 are bent toward the bottom of the bottom chassis;

FIG. 4 is a schematic cross-sectional view illustrating an example of a first substrate, a second substrate, and a pixel array layer of the display panel;

FIG. 5 is a layout view of a front portion of a flexible film according to an embodiment;

FIG. 6 is a layout view of a rear portion of the flexible film according to the embodiment of FIG. 5;

FIG. 7 is a layout view of a front portion of a flexible film according to an embodiment; and

FIG. 8 is a schematic diagram illustrating a second independent line passing between bumps of a display driver IC (DDI) according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, specific embodiments will be described with reference to the accompanying drawings.

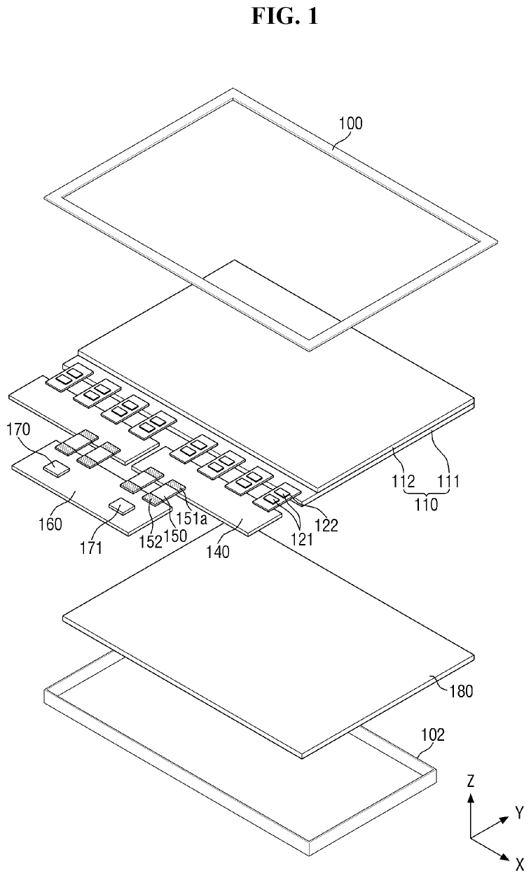

FIG. 1 is an exploded perspective view of a display device 10 according to an embodiment.

Referring to FIG. 1, the display device 10 according to the embodiment may be applied to mobile electronic devices such as mobile phones, smartphones, tablet personal computers (PCs), mobile communication terminals, electronic notebooks, electronic books, portable multimedia players (PMPs), navigation devices, and ultra-mobile PCs (UMPCs). The display device 10 according to the embodiment may be applied as a display portion of a television, a notebook computer, a monitor, a billboard, or an Internet of things (IoT) device. The display device 10 according to the embodiment may be applied to wearable devices such as smart watches, watch phones, glasses-type displays, and head-mounted displays (HMDs). The display device 10 according to the embodiment may be applied to a dashboard of a vehicle, a center fascia of a vehicle, a center information display (CID) disposed on a dashboard of a vehicle, a room mirror display replacing side mirrors of a vehicle, or a display disposed on the back of a front seat as for entertainment for rear-seat passengers of a vehicle.

Referring to FIG. 1, the display device 10 according to the embodiment may include an upper set cover 100, a lower set cover 102, a display panel 110, source driving circuits 121, flexible films 122, source circuit boards 140, first cables 150, a control circuit board 160, a power circuit 171, and a timing control circuit 170.

In the specification, the terms “above”, “top”, and “upper surface” refer to a direction in which a second substrate 112 may be disposed with respect to a first substrate 111 of the display panel 110, for example, a third direction (Z-axis direction), and the terms “below,” “bottom”, and “lower surface” may be a direction opposite to the third direction (Z-axis direction). The terms “left,” “right,” “upper” and “lower” refer to directions when the display panel 110 may be viewed in a plan view. For example, “left” refers to a first direction (X-axis direction), “right” refers to a direction opposite to the first direction (X-axis direction), “upper” refers to a second direction (Y-axis direction), and “lower” refers to a direction opposite to the second direction (Y-axis direction),

The upper set cover 100 may be placed to cover edges of an upper surface of the display panel 110. The upper set cover 100 may cover a non-display area of the display panel 110 excluding a display area. In case that the source circuit boards 140, the first cables 150, and the control circuit board 160 are disposed under the display panel 110 due to the bending of the flexible films 122, the lower set cover 102 may cover the source circuit boards 140, the first cables 150, and the control circuit board 160.

A length of the lower set cover 102 in the second direction (Y-axis direction) may be greater than a length of a bottom chassis 180 in the second direction (Y-axis direction) or may be substantially equal to the length of the bottom chassis 180 in the second direction (Y-axis direction). The upper set cover 100 and the lower set cover 102 may be made of plastic or metal or may include both plastic and metal.

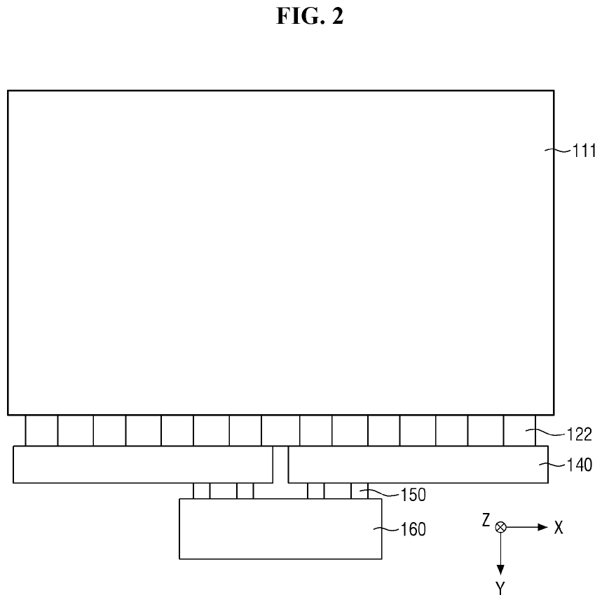

The display panel 110 may be rectangular in a plan view. For example, the display panel 110 may have a rectangular planar shape having long sides extending in the first direction (X-axis direction) and short sides extending in the second direction (Y-axis direction) as illustrated in FIG. 2. Each corner where a long side extending in the first direction (X-axis direction) meets a short side extending in the second direction (Y-axis direction) may be right-angled or may be rounded with a curvature (e.g., predetermined or selectable curvature). The planar shape of the display panel 110 may not be limited to the rectangular shape and may also be other polygonal shapes, a circular shape, or an oval shape.

Although the display panel 110 may be formed approximately flat in FIG. 1, the specification may not be limited to this case. The display panel 110 may also include a curved portion bent with a curvature (e.g., predetermined or selectable curvature),

The display panel 110 may include the first substrate 111 and the second substrate 112. The second substrate 112 may face a first surface of the first substrate 111. The first substrate 111 and the second substrate 112 may be rigid or flexible. The first substrate 111 may be made of glass or plastic. The second substrate 112 may be made of glass, plastic, an encapsulation film, or a barrier film. The second substrate 112 may be omitted. In case that the first substrate 111 and the second substrate 112 may be made of plastic, the plastic may be polyethersulfone (PES), polyacrylate (PA), polyarylate (PAR), polyetherimide (PEI), polyethylene naphthalate (PEN), polyethylene terephthalate (PET), polyphenylene sulfide (PPS), polyacrylate, polyimide (PI), polycarbonate (PC), cellulose triacetate (CAT), cellulose acetate propionate (CAP), or a combination thereof. The encapsulation film or the barrier film may be a film in which multiple inorganic layers may be stacked on each other.

The display panel 110 may be an organic light emitting display panel using an organic light emitting diode including a first electrode, an organic light emitting layer and a second electrode, an inorganic light emitting display panel using an inorganic light emitting diode including a first electrode, an inorganic semiconductor layer and a second electrode, or a quantum dot light emitting display panel including a quantum dot light emitting diode including a first electrode, a quantum dot light emitting layer and a second electrode.

The display panel 110 may be described below as an organic light emitting display panel including a thin-film transistor layer TFTL, a light emitting element layer EML, a filler FL, a light wavelength conversion layer QDL, and a color filter layer CFL between the first substrate 111 and the second substrate 112. The first substrate 111 may be a thin-film transistor substrate on which the thin-film transistor layer TFTL, the light emitting element layer EML and a thin-film encapsulation layer TFEL may be formed, the second substrate 112 may be a color filter substrate on which the light wavelength conversion layer QDL and the color filter layer CFL may be formed, and the filler FL may be disposed between the thin-film encapsulation layer TFEL of the first substrate 111 and the light wavelength conversion layer QDL of the second substrate 112.

The second substrate 112 of the display panel 110 may be omitted, and a thin-film encapsulation layer may be disposed on the light emitting element layer EML. The filler FL may be omitted, and the light wavelength conversion layer QDL and the color filter layer CFL may be disposed on the thin-film encapsulation layer.

A side of each of the flexible films 122 may be disposed on the first surface of the first substrate 111 of the display panel 110, and another side may be attached onto a surface of one of the source circuit boards 140. Specifically, since the first substrate 111 may be larger in size than the second substrate 112, a side of the first substrate 111 may be exposed without being covered by the second substrate 112. The flexible films 122 may be attached to the exposed side of the first substrate 111 which may not be covered by the second substrate 112. Each of the flexible films 122 may be attached onto the first surface of the first substrate 111 and the surface of one of the source circuit boards 140 by using an anisotropic conductive film.

Each of the flexible films 122 may be a flexible film such as a tape carrier package or a chip on film. The flexible films 122 may be bent toward the bottom of the first substrate 111. Although eight flexible films 122 may be attached onto the first substrate 111 of the display panel 110 in FIG. 1, the number of flexible films 122 may not be limited to eight in the specification.

The source driving circuits 121 may be disposed on a surface of each of the flexible films 122. The source driving circuits 121 may be formed as integrated circuits. Each of the source driving circuits 121 converts digital video data into analog data voltages according to a source control signal of the timing control circuit 170 and supplies the analog data voltages to data lines of the display panel 110 through a flexible film 122. The source driving circuits 121 may be referred to as display driver ICs (DDIs).

The display panel 110 may include scan lines intersecting the data lines and pixels disposed in areas defined by the data lines and the scan lines. The scan lines may receive scan signals from a scan driver formed on the display panel 110. The scan driver may include multiple thin-film transistors and generate scan signals according to a scan control signal of the timing control circuit 170. Each of the pixels may be electrically connected to at least one data line and at least a scan line and may receive a data voltage of the data line in case that a scan signal is supplied to the scan line.

Each of the source circuit boards 140 may be electrically connected to the control circuit board 160 through the first cables 150. Each of the source circuit boards 140 may include first connectors 151a for connection to the first cables 150. The source circuit boards 140 may be flexible printed circuit boards or printed circuit boards. The first cables 150 may be flexible cables.

The control circuit board 160 may be electrically connected to the source circuit boards 140 through the first cables 150. To this end, the control circuit board 160 may include second connectors 152 for connection to the first cables 150.

Although four first cables 150 connect the source circuit boards 140 and the control circuit board 160 in FIG. 1, the number of first cables 150 may not be limited to four in the specification. Although two source circuit boards 140 are illustrated in FIG. 1, the number of source circuit boards 140 may not be limited to two in the specification.

In case that the number of flexible films 122 is small, the source circuit boards 140 may be omitted. The flexible films 122 may be connected (e.g., directly connected) to the control circuit board 160.

The timing control circuit 170 may be disposed on a surface of the control circuit board 160. The timing control circuit 170 may be formed as an integrated circuit. The timing control circuit 170 may receive digital video data and timing signals from a system on chip of a system circuit board and generate a source control signal for controlling the timings of the source driving circuits 121 according to the timing signals.

The power circuit 171 may be disposed on the surface of the control circuit board 160. The power circuit 171 may be formed as an integrated circuit. The power circuit 171 may generate voltages desirable for driving the display panel 110 from main power received from the system circuit board and supply the generated voltages to the display panel 110. For example, the power circuit 171 may generate a high-potential voltage, a low-potential voltage and an initialization voltage for driving organic light emitting elements and supply the generated voltages to the display panel 110. The power circuit 171 may generate and supply driving voltages for driving the source driving circuits 121, the timing control circuit 170, etc.

The system on chip may be mounted on the system circuit board electrically connected to the control circuit board 160 through a flexible cable and may be formed as an integrated circuit. The system on chip may be a processor of a smart television, a central processing unit (CPU) or graphics card of a computer or notebook, or an application processor of a smartphone or tablet PC. The system circuit board may be a flexible printed circuit board or a printed circuit board.

Although the display device 10 according to the embodiment may be illustrated as a medium/large display device including multiple source driving circuits 121 in FIG. 1, the specification may not be limited to this case. For example, the display device 10 according to the embodiment may also be a small display device including one source driving circuit 121. The flexible films 122, the source circuit boards 140, and the first cables 150 may be omitted. The source driving circuits 121 and the timing control circuit 170 may be integrated into one integrated circuit and then attached onto one flexible circuit board or attached onto the first substrate 111 of the display panel 110. Examples of the medium/large display device include monitors and televisions, and examples of the small display device include smartphones and tablet PCs.

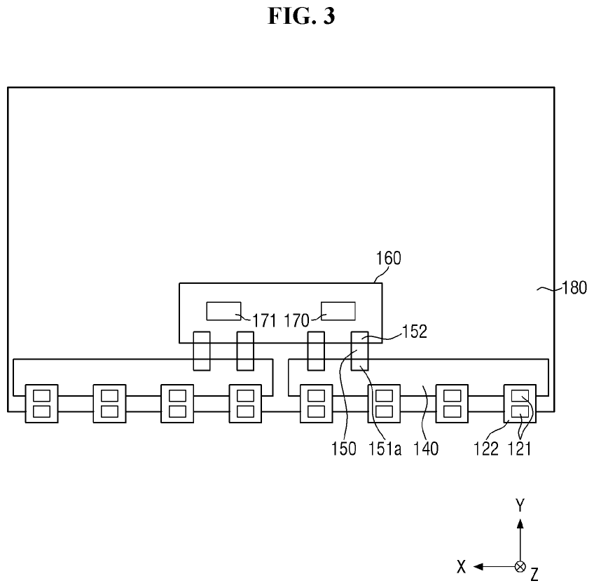

FIG. 2 is a bottom view illustrating an example of the display panel 110 in case that the flexible films 122 in FIG. 1 are unfolded. FIG. 3 is a bottom view illustrating an example of the display panel 110 to which the bottom chassis 180 may be coupled in case that the flexible films 122 in FIG. 1 are bent toward the bottom of the bottom chassis 180.

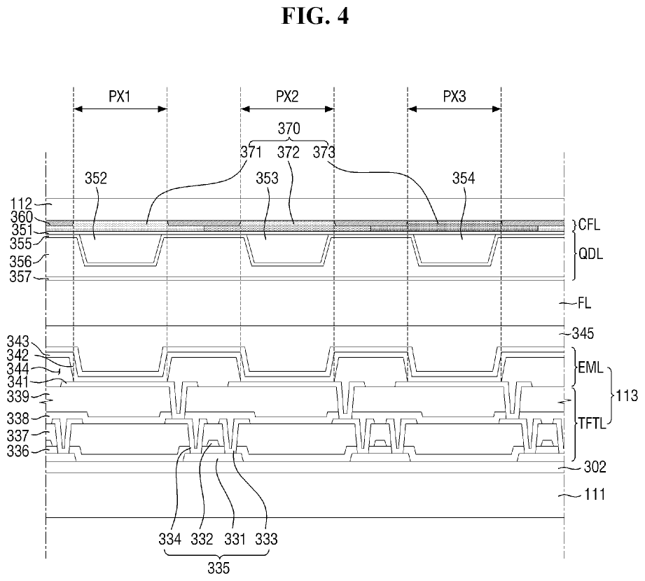

Referring to FIGS. 2 and 3, the first surface of the first substrate 111 and a first surface of the second substrate 112 may face each other. A pixel array layer 113 (see FIG. 4) may be disposed between the first surface of the first substrate 111 and the first surface of the second substrate 112. The pixel array layer 113 may include multiple pixels PX1 through PX3 which emit light.

A heat dissipation film (not illustrated) may be disposed on a second surface of the first substrate 111. The heat dissipation film may include a metal layer having high thermal conductivity, such as graphite, silver (Ag), copper (Cu) or aluminum (Al).

The flexible films 122 may be bent toward the bottom of the bottom chassis 180 and attached to the source circuit boards 140 on a surface of the bottom chassis 180. The source circuit boards 140 and the control circuit board 160 may be disposed on the surface of the bottom chassis 180 and may be electrically connected to each other through the first cables 150.

The timing control circuit 170 and the power circuit 171 may be disposed on the control circuit board 160.

FIG. 4 is a schematic cross-sectional view illustrating an example of the first substrate 111, the second substrate 112, and the pixel array layer 113 of the display panel 110.

Referring to FIG. 4, the display panel 110 may include the first substrate 111, the second substrate 112, and the pixel array layer 113. The pixel array layer 113 may include the thin-film transistor layer TFTL and the light emitting element layer EML.

A buffer layer 302 may be formed on a surface of the first substrate 111 which faces the second substrate 112. The buffer layer 302 may be formed on the first substrate 111 to protect thin-film transistors 335 and light emitting elements from moisture introduced through the first substrate 111 which may be vulnerable to moisture penetration. The buffer layer 302 may be composed of multiple inorganic layers stacked alternately on each other. For example, the buffer layer 302 may be a multilayer in which one or more inorganic layers selected from a silicon oxide (SiOₓ) layer, a silicon nitride (SiNₓ) layer, and SiON may be alternately stacked on each other. The buffer layer 302 may also be omitted.

The thin-film transistor layer TFTL may be formed on the buffer layer 302. The thin-film transistor layer TFTL includes the thin-film transistors 335, a gate insulating layer 336, an interlayer insulating film 337, a protective layer 338, and a planarization layer 339.

The thin film transistors 335 may be formed on the buffer layer 302. Each of the thin-film transistors 335 includes an active layer 331, a gate electrode 332, a source electrode 333, and a drain electrode 334. In FIG. 4, each of the thin-film transistors 335 may be formed as a top-gate type in which the gate electrode 332 may be located above the active layer 331. However, it should be noted that the specification may not be limited to this case. For example, each of the thin-film transistors 335 may also be formed as a bottom-gate type in which the gate electrode 332 may be located below the active layer 331 or a double-gate type in which the gate electrode 332 may be located both above and below the active layer 331.

The active layers 331 may be formed on the buffer layer 302. The active layers 331 may be made of a silicon-based semiconductor material or an oxide-based semiconductor material. A light shielding layer may be formed between the buffer layer 302 and the active layers 331 to block external light from entering the active layers 331.

The gate insulating layer 336 may be formed on the active layers 331. The gate insulating layer 336 may be an inorganic layer, for example, a SiOₓ layer, a SiN, layer, or a multilayer composed of these layers.

The gate electrodes 332 and gate lines may be formed on the gate insulating layer 336. Each of the gate electrodes 332 and the gate lines may be a single layer or a multilayer made of any one or more of molybdenum (Mo), aluminum (AI), chromium (Cr), gold (Au), titanium (Ti), nickel (Ni), neodymium (Nd), copper (Cu), alloys thereof, or a combination thereof.

The interlayer insulating film 337 may be formed on the gate electrodes 332 and the gate lines. The interlayer insulating film 337 may be an inorganic layer, for example, a SiOₓ layer, a SiN, layer, or a multilayer composed of these layers.

The source electrodes 333, the drain electrodes 334, and data lines may be formed on the interlayer insulating film 337. Each of the source electrodes 333 and the drain electrodes 334 may be electrically connected to an active layer 331 through a contact hole penetrating the gate insulating layer 336 and the interlayer insulating film 337. Each of the source electrodes 333, the drain electrodes 334 and the data lines may be a single layer or a multilayer made of any one or more of molybdenum (Mo), aluminum (Al), chromium (Cr), gold (Au), titanium (Ti), nickel (Ni), neodymium (Nd), copper (Cu), alloys thereof, or a combination thereof.

The protective layer 338 for insulating the thin-film transistors 335 may be formed on the source electrodes 333, the drain electrodes 334, and the data lines. The protective layer 338 may be an inorganic layer, for example, a SiO, layer, a SiN, layer, or a multilayer composed of these layers.

The planarization layer 339 may be formed on the protective layer 338 to planarize steps due to the thin-film transistors 335. The planarization layer 339 may be made of an organic layer such as acryl resin, epoxy resin, phenolic resin, polyamide resin, polyimide resin, or a combination thereof.

The light emitting element layer EML may be formed on the thin-film transistor layer TFTL. The light emitting element layer EML includes the light emitting elements and a pixel defining layer 344.

The light emitting elements and the pixel defining layer 344 may be formed on the planarization layer 339. The light emitting elements may be organic light emitting devices. Each of the light emitting elements may include an anode 341, a light emitting layer 342, and a cathode 343.

The anodes 341 may be formed on the planarization layer 339. The anodes 341 may be electrically connected to the drain electrodes 334 of the thin-film transistors 335 through contact holes penetrating the protective layer 338 and the planarization layer 339.

The pixel defining layer 344 may be formed on the planarization layer 339 and may cover edges of the anodes 341 to define pixels. For example, the pixel defining layer 344 may serve as a pixel defining layer for defining subpixels PX1 through PX3. Each of the subpixels PX1 through PX3 may be an area in which the anode 341, the light emitting layer 342 and the cathode 343 may be sequentially stacked on each other so that holes from the anode 341 and electrons from the cathode 343 may combine together in the light emitting layer 342 to emit light.

The light emitting layer 342 may be formed on the anodes 341 and the pixel defining layer 344. The light emitting layer 342 may be an organic light emitting layer. The light emitting layer 342 may emit light having a short wavelength, such as blue light or ultraviolet light. The blue light may have a peak wavelength range of about 450 to about 490 nm, and the ultraviolet light may have a peak wavelength range of less than about 450 nm. The light emitting layer 342 may be a common layer common to all of the subpixels PX1 through PX3. The display panel 110 may include the light wavelength conversion layer QDL for converting short-wavelength light such as blue light or ultraviolet light emitted from the light emitting layer 342 into red light, green light and blue light and the color filter layer CFL for transmitting each of the red light, green light and the blue light.

The light emitting layer 342 may include a hole transporting layer, a light emitting layer, and an electron transporting layer. The light emitting layer 342 may be formed in a tandem structure of two or more stacks. A charge generating layer may be formed between the stacks.

The cathode 343 may be formed on the light emitting layer 342. The cathode 343 may be formed to cover the light emitting layer 342. The cathode 343 may be a common layer common to all pixels.

The light emitting element layer EML may be formed as a top emission type which emits light toward the second substrate 112, for example, in an upward direction. The anodes 341 may be made of a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy may be an alloy of silver (Ag), palladium (Pd), and copper (Cu). The cathode 343 may be made of a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. In case that the cathode 343 is made of a semi-transmissive conductive material, light output efficiency may be increased by a microcavity.

An encapsulation layer 345 may be formed on the light emitting element layer EML. The encapsulation layer 345 serves to prevent oxygen or moisture from permeating into the light emitting layer 342 and the cathode 343. To this end, the encapsulation layer 345 may include at least one inorganic layer. The inorganic layer may be made of silicon nitride, aluminum nitride, zirconium nitride, titanium nitride, hafnium nitride, tantalum nitride, silicon oxide, aluminum oxide, titanium oxide, or a combination thereof. The encapsulation layer 345 may further include at least one organic layer. The organic layer may be formed to a sufficient thickness to prevent particles from penetrating the encapsulation layer 345 and entering the light emitting layer 342 and the cathode 343. The organic layer may include any one of epoxy, acrylate, urethane acrylate, or a combination thereof.

The color filter layer CFL may be disposed on a surface of the second substrate 112 which faces the first substrate 111. The color filter layer CFL may include a black matrix 360 and color filters 370.

The black matrix 360 may be formed on the surface of the second substrate 112. The black matrix 360 may not overlap the subpixels PX1 through PX3 and may overlap the pixel defining layer 344. The black matrix 360 may include black dye capable of blocking light or an opaque metal material.

The color filters 370 may overlap the subpixels PX1 through PX3. A first color filter 371 may overlap a first subpixel PX1, a second color filter 372 may overlap a second subpixel PX2, and a third color filter 373 may overlap a third subpixel PX3. The first color filter 371 may be a first-color light transmitting filter that transmits light of a first color, the second color filter 372 may be a second-color light transmitting filter that transmits light of a second color, and the third color filter 373 may be a third-color light transmitting filter that transmits light of a third color. For example, the first color may be red, the second color may be green, and the third color may be blue, but the specification may not be limited thereto. The peak wavelength range of red light transmitted through the first color filter 371 may be in a range of about 620 to about 750 nm, the peak wavelength range of green light transmitted through the second color filter 372 may be in a range of about 500 to about 570 nm, and the peak wavelength range of blue light transmitted through the third color filter 373 may be in a range of about 450 to about 490 nm.

Edges of two adjacent color filters may overlap the black matrix 360. Therefore, the black matrix 360 can prevent color mixing that occurs in case that light emitted from the light emitting layer 342 of any one subpixel travels to a color filter of an adjacent subpixel.

An overcoat layer may be formed on the color filters 370 to planarize steps due to the color filters 370 and the black matrix 360. The overcoat layer may also be omitted.

The light wavelength conversion layer QDL may be disposed on the color filter layer CFL. The light wavelength conversion layer QDL may include a first capping layer 351, a first wavelength conversion layer 352, a second wavelength conversion layer 353, a third wavelength conversion layer 354, a second capping layer 355, an interlayer organic film 356, and a third capping layer 357.

The first capping layer 351 may be disposed on the color filter layer CFL. The first capping layer 351 may prevent moisture or oxygen from permeating into the first wavelength conversion layer 352, the second wavelength conversion layer 353 and the third wavelength conversion layer 354 from the outside through the color filter layer CFL. The first capping layer 351 may be made of an inorganic layer such as silicon nitride, aluminum nitride, zirconium nitride, titanium nitride, hafnium nitride, tantalum nitride, silicon oxide, aluminum oxide, titanium oxide, or a combination thereof.

The first wavelength conversion layer 352, the second wavelength conversion layer 353 and the third wavelength conversion layer 354 may be disposed on the first capping layer 351.

The first wavelength conversion layer 352 may overlap the first subpixel PX1. The first wavelength conversion layer 352 may convert short-wavelength light such as blue light or ultraviolet light emitted from the light emitting layer 342 of the first subpixel PX into light of the first color. To this end, the first wavelength conversion layer 352 may include a first base resin, first wavelength shifters, and first scatterers.

The first base resin may be a material having high light transmittance and superior dispersion characteristics for the first wavelength shifters and the first scatterers. For example, the first base resin may include an organic material such as epoxy resin, acrylic resin, cardo resin, imide resin, or a combination thereof.

The first wavelength shifters may convert or shift the wavelength range of incident light. The first wavelength shifters may be quantum dots, quantum rods, or phosphors. In case that the first wavelength shifters may be quantum dots, they may have a specific band gap according to their composition and size as semiconductor nanocrystalline materials. Thus, the first wavelength shifters may absorb incident light and then emit light having a unique wavelength. The first wavelength shifters may have a core-shell structure including a core containing a nanocrystal and a shell surrounding the core. Examples of the nanocrystal that forms the core include group IV nanocrystals, group II-VI compound nanocrystals, group III-V compound nanocrystals, group IV-VI nanocrystals, and combinations thereof. The shell may serve as a protective layer for maintaining semiconductor characteristics by preventing chemical denaturation of the core and/or as a charging layer for giving electrophoretic characteristics to the quantum dot. The shell may be a single layer or a multilayer. The shell may be, for example, a metal or non-metal oxide, a semiconductor compound, or a combination thereof.

The first scatterers may have a refractive index different from that of the first base resin and may form an optical interface with the first base resin. For example, the first scatterers may be light scattering particles. For example, the first scatterers may be metal oxide particles such as titanium oxide (TiO₂), silicon oxide (SiO₂), zirconium oxide (ZrO₂), aluminum oxide (Al₂O₃), indium oxide (In₂O)₃), zinc oxide (ZnO), tin oxide (SnO₂), or a combination thereof. The first scatterers may be organic particles such as acrylic resin or urethane resin.

The first scatterers may scatter incident light in random directions without substantially changing the wavelength of the light transmitted through the first wavelength conversion layer 352. Accordingly, the length of the path of the light transmitted through the first wavelength conversion layer 352 may be increased, thereby increasing the color conversion efficiency of the first wavelength shifters.

The first wavelength conversion layer 352 may overlap the first color filter 371. Therefore, a portion of short-wavelength light such as blue light or ultraviolet light provided from the first subpixel PX1 may pass through the first wavelength conversion layer 352 as is without being converted into light of the first color by the first wavelength shifters. However, the short-wavelength light such as blue light or ultraviolet light incident on the first color filter 371 without being converted by the first wavelength conversion layer 352 cannot pass through the first color filter 371. On the other hand, light of the first color into which the short-wavelength light has been converted by the first wavelength conversion layer 352 can pass through the first color filter 371 and proceed toward the second substrate 112.

The second wavelength conversion layer 353 may overlap the second subpixel PX2. The second wavelength conversion layer 353 may convert short-wavelength light such as blue light or ultraviolet light emitted from the light emitting layer 342 of the second subpixel PX2 into light of the second color. To this end, the second wavelength conversion layer 353 may include a second base resin, second wavelength shifters, and second scatterers. The second base resin, the second wavelength shifters and the second scatterers of the second wavelength conversion layer 353 may be substantially the same as those of the first wavelength conversion layer 353, and thus a detailed description thereof may be omitted. In case that the first wavelength shifters and the second wavelength shifters are quantum dots, a diameter of the second wavelength shifters may be smaller than that of the first wavelength shifters.

The second wavelength conversion layer 353 may overlap the second color filter 372. Therefore, a portion of short-wavelength light such as blue light or ultraviolet light provided from the second subpixel PX2 can pass through the second wavelength conversion layer 353 as is without being converted into light of the second color by the second wavelength shifters. However, the short-wavelength light such as blue light or ultraviolet light incident on the second color filter 372 without being converted by the second wavelength conversion layer 353 cannot pass through the second color filter 372. On the other hand, light of the second color into which the short-wavelength light has been converted by the second wavelength conversion layer 353 can pass through the second color filter 372 and proceed toward the second substrate 112.

The third wavelength conversion layer 354 may overlap the third subpixel PX3. The third wavelength conversion layer 354 may convert short-wavelength light such as blue light or ultraviolet light emitted from the light emitting layer 342 of the third subpixel PX3 into light of the third color. To this end, the third wavelength conversion layer 354 may include a third base resin and third scatterers. The third base resin and the third scatterers of the third wavelength conversion layer 354 may be substantially the same as those of the first wavelength conversion layer 352, and thus a detailed description thereof is omitted.

The third wavelength conversion layer 354 may overlap the third color filter 373. Therefore, short-wavelength light such as blue light or ultraviolet light provided from the third subpixel PX3 can pass through the third wavelength conversion layer 354 as is, and the light that passes through the third wavelength conversion layer 354 can pass through the third color filter 373 and proceed toward the second substrate 112.

The second capping layer 355 may be disposed on the first wavelength conversion layer 352, the second wavelength conversion layer 353, the third wavelength conversion layer 354, and the first capping layer 351 exposed without being covered by the wavelength conversion layers 352 through 354. The second capping layer 355 prevents moisture or oxygen from permeating into the first wavelength conversion layer 352, the second wavelength conversion layer 353 and the third wavelength conversion layer 354 from the outside. The second capping layer 355 may be made of an inorganic layer such as silicon nitride, aluminum nitride, zirconium nitride, titanium nitride, hafnium nitride, tantalum nitride, silicon oxide, aluminum oxide, titanium oxide, or a combination thereof.

The interlayer organic film 356 may be disposed on the second capping layer 355. The interlayer organic film 356 may be a planarization layer for planarizing steps due to the wavelength conversion layers 352 through 354. The interlayer organic film 356 may be made of an organic layer such as acryl resin, epoxy resin, phenolic resin, polyamide resin, polyimide resin, or a combination thereof.

The third capping layer 357 may be disposed on the interlayer organic film 356. The third capping layer 357 may be made of an inorganic layer such as silicon nitride, aluminum nitride, zirconium nitride, titanium nitride, hafnium nitride, tantalum nitride, silicon oxide, aluminum oxide, titanium oxide, or a combination thereof.

The filler FL may be disposed between the thin-film encapsulation layer TFEL disposed on the first substrate 111 and the third capping layer 357 disposed on the second substrate 112. The filler FL may be made of a material having a buffer function. For example, the filler FL may be made of an organic layer such as acryl resin, epoxy resin, phenolic resin, polyamide resin, polyimide resin, or a combination thereof.

A sealing material for bonding the first substrate 111 and the second substrate 112 together may be disposed in the non-display area of the display panel 110. When seen in a plan view, the filler FL may be surrounded by the sealing material. The sealing material may be glass frit or a sealant.

According to the embodiment illustrated in FIG. 4, the first through third subpixels PX1 through PX3 may emit short-wavelength light such as blue light or ultraviolet light. Light of the first subpixel PX1 may be converted into light of the first color by the first wavelength conversion layer 352 and then output through the first color filter 371. Light of the second subpixel PX2 may be converted into light of the second color by the second wavelength conversion layer 353 and then output through the second color filter 372. Light of the third subpixel PX3 may be output through the third wavelength conversion layer 354 and the third color filter 373. Therefore, white light can be output.

According to the embodiment illustrated in FIG. 4, each of the subpixels PX1 through PX3 may be formed as a top emission type which emits light toward the second substrate 112, for example, in the upward direction. Therefore, the heat dissipation film including an opaque material such as graphite or aluminum may be disposed on another surface of the first substrate 111.

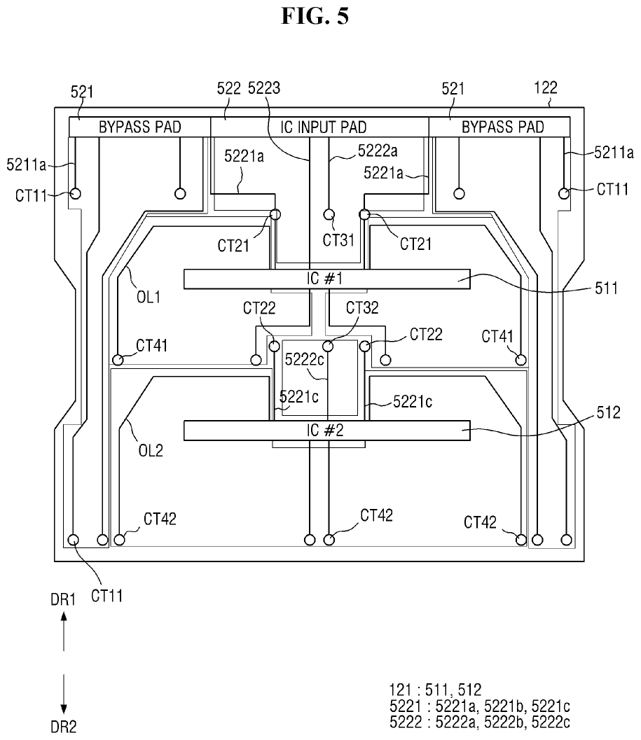

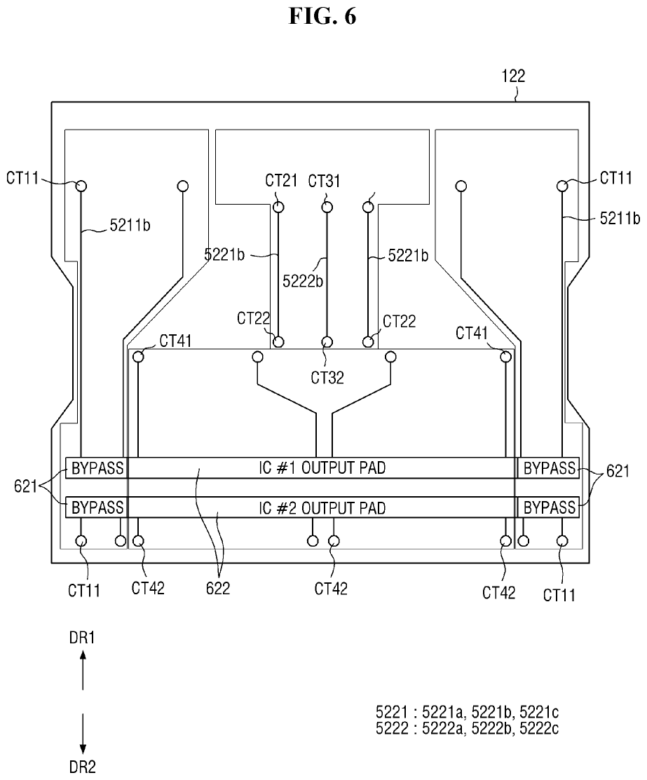

FIG. 5 is a layout view of a front portion of a flexible film 122 according to an embodiment. FIG. 6 is a layout view of a rear portion of the flexible film 122 according to the embodiment.

Referring to FIGS. 5 and 6, the display device according to the embodiment may include multiple flexible films 122 attached to a side of the display panel 110, and multiple DDIs may be disposed on each flexible film 122. For example, a first DDI 511 and a second DDI 512 may be disposed on one flexible film 122.

According to an embodiment, each flexible film 122 may include the first DDI 511 and the second DDI 512 spaced apart from each other on a surface of the flexible film 122. Each of the first DDI 511 and the second DDI 512 drives a portion of the display area of the display panel 110. For example, the first DDI 511 drives first subpixels disposed in a first display area of the display panel 110. The second DDI 512 drives second subpixels disposed in a second display area adjacent to the first display area.

According to an embodiment, the first DDI 511 and the second DDI 512 may have the same circuitry. For example, a circuit included in the first DDI 511 and a circuit included in the second DDI 512 may be the same. For example, the first DDI 511 and the second DDI 512 may be parts that drive different display areas of the display panel 110 but have the same circuitry. Therefore, signals or power input to the first DDI 511 may be the same as signals or power input to the second DDI 512. Signals or power output from the first DDI 511 may be the same as signals or power output from the second DDI 512. However, the driving timing of the first DDI 511 may be different from the driving timing of the second DDI 512. Therefore, some of the signals input to the first DDI 511 may be independent of the signals input to the second DDI 512.

According to an embodiment, each flexible film 122 may include common lines for supplying signals or power to be commonly input to the first DDI 511 and the second DDI 512 disposed on the flexible film 122. Each flexible film 122 may include independent lines for supplying signals or power to be independently input to the first DDI 511 and the second DDI 512 disposed on the flexible film 122. In the specification, the term “common line” may be replaced with a term such as, but not limited to “first line”. In the specification, the term “independent line” may be replaced with a term such as, but not limited to, “second line”.

According to an embodiment, the power or signals input to each of the first DDI 511 and the second DDI 512 through lines (i.e., common lines or independent lines) provided in each flexible film 122 may include IC logic power, gamma power, sensing reference power, a clock signal, option signals, and control signals. Among these, the gamma power, the sensing reference power, and the clock signal may be power or signals commonly input to the first DDI 511 and the second DDI 512. Such common power or common signals may be input to the first DDI 511 and the second DDI 512 through common lines provided in each flexible film 122. In an electronic device according to an embodiment, common signals or power among the signals or power input to multiple DDIs (e.g., the first DDI 511 and the second DDI 512) disposed on each flexible film 122 may be transmitted through a line. Therefore, the number of lines and pads in the flexible film 122 can be reduced.

The structures and forms of common lines according to an embodiment will now be described in detail.

According to an embodiment, each flexible film 122 includes the first DDI 511 and the second DDI 512, and the first DDI 511 and the second DDI 512 may be spaced apart from each other. The first DDI 511 may be disposed between an input pad 522 of the flexible film 122 and the second DDI 512.

In the flexible film 122, the input pad 522 may be disposed on a side of the flexible film 122, and output pads 622 may be disposed on another side of the flexible film 122.

The input pad 522 of the flexible film 122 receives power or signals to be input to the first DDI 511 and the second DDI 512. Bypass input pads 521 may be disposed on both sides of the input pad 522, respectively. The bypass input pads 521 may receive signals that bypass the flexible film 122 without being input to the first DDI 511 and the second DDI 512.

The output pads 622 of the flexible film 122 receive signals or power output from the first DDI 511 and the second DDI 512 and transmit the received signals or power to the display panel 110. Bypass output pads 621 may be respectively disposed on both sides of each of the output pads 622. The bypass output pads 621 may transmit signals that bypass the flexible film 122 without being input to the first DDI 511 and the second DDI 512.

According to an embodiment, one or more common lines 5221 and one or more independent lines 5223 and 5222 may be disposed between the input pad 522 and the first DDI 511 and/or between the input pad 522 and the second DDI 512.

According to an embodiment, the common lines 5221 may include first common lines 5221a, second common lines 5221b, and third common lines 5221c. Of the independent lines 5223 and 5222, the second independent line 5222 may include three portions 5222a, 5222b, and 5222c.

The first common lines 5221a may be disposed between the input pad 522 and the first DDI 511 and connect the input pad 522 and the first DDI 511. The second common lines 5221b branch from the first common lines 5221a and extend under the first DDI 511 to bypass the first DDI 511. The third common lines 5221c may be electrically connected to the second common lines 5221b and connect the second common lines 5221b and the second DDI 512.

The first independent line 5223 may be disposed between the input pad 522 and the first DDI 511 and may connect the input pad 522 and the first DDI 511. The second independent line 5222 may be disposed between the input pad 522 and the second DDI 512 and may connect the input pad 522 and the second DDI 512. A portion (5222b) of the second independent line 5222 may extend to bypass the bottom of the first DDI 511.

As illustrated in FIGS. 5 and 6, the flexible film 122 according to the embodiment may have a multilayer structure including multiple metal layers. For example, each flexible film 122 may include a first metal layer adjacent to a front surface of the flexible film 122 and a second metal layer adjacent to a rear surface of the flexible film 122. Each of the first metal layer and the second metal layer may include lines for transmitting signals or power. For example, FIG. 5 illustrates lines included in the first metal layer, and the illustrated lines may serve as lines for transmitting signals or power. FIG. 6 illustrates lines included in the second metal layer, and the illustrated lines may serve as lines for transmitting signals or power.

According to an embodiment, as illustrated in FIG. 5, the first common lines 5221a and the third common lines 5221c may be disposed in the first metal layer. The second common lines 5221b may be disposed in the second metal layer as illustrated in FIG. 6. Each flexible film 122 may include through holes CT21 and CT22 in which the second common lines 5221b disposed in the second metal layer and each of the first common lines 5221a and the third common lines 5221c disposed in the first metal layer may be electrically connected. The through holes CT21 and CT22 penetrate portions of the flexible film 122 and connect the first metal layer and the second metal layer.

According to an embodiment, the through holes CT21 and CT22 may include first through holes CT21 in which the first common lines 5221a and ends of the second common lines 5221b may be electrically connected, and second through holes CT22 in which the third common lines 5221c and the other ends of the second common lines 5221b may be electrically connected. Therefore, among the signals or power input to multiple DDIs (e.g., the first DDI 511 and the second DDI 512) disposed on each flexible film 122, common signals or power may be input to the first DDI 511 via the input pad 522 and the first common lines 5221a. Among the signals or powers input to the DDIs (e.g., the first DDI 511 and the second DDI 512) disposed on each flexible film 122, the common signals or power may be input to the second DDI 512 via the input pad 522, the first common lines 5221a, the first through holes CT21, the second common lines 5221b, the second through holes CT22, and the third common lines 5221c. The first through holes CT21 may be disposed between the first DDI 511 and the input pad 522, and the second through holes CT22 may be disposed between the first DDI 511 and the second DDI 512.

Power or signals for independently controlling the first DDI 511 and the second DDI 512 may be individually input to the first DDI 511 and the second DDI 512 through the independent lines 5223 and 5222. The first independent line 5223 may be disposed between the input pad 522 and the first DDI 511 to connect the first DDI 511 and the input pad 522 to each other. A first portion 5222a of the second independent line 5222 may be electrically connected to a second portion 5222b of the second independent line 5222 disposed in the second metal layer through a through hole CT31 disposed between the input pad 522 and the first DDI 511. The second portion 5222b of the second independent line 5222 may be electrically connected to a third portion 5222c of the second independent lines 5222 disposed in the first metal layer via a through hole CT32 disposed between the first DDI 511 and the second DDI 512. The third portion 5222c of the second independent line 5222 may extend from the through hole CT32 to the second DDI 512 and thus may transmit independent power or signals to the second DDI 512.

According to an embodiment, bypass lines 5211a and 5211b that bypass the first DDI 511 and the second DDI 512 may be respectively disposed on both sides of each flexible film 122. Some of the bypass lines 5211a and 5211b connect the bypass input pads 521 and the bypass output pads 621 to each other through the first metal layer. Some of the bypass lines 5211a and 5211b connect the bypass input pads 521 and the bypass output pads 621 to each other through the first metal layer and the second metal layer. Through holes CT11 may be included that electrically connect the first metal layer and the second metal layer of bypass lines 5211a and 5211b.

Signals or power output from each of the first DDI 511 and the second DDI 512 may be transmitted to the output pads 622 of each flexible film 122 through output lines OL1 and OL2 provided in the flexible film 122. The output lines OL1 and OL2 may include first output lines OL1 which transmit signals or power output from the first DDI 511 to the output pads 622 and second output lines OL2 which transmit signals or power output from the second DDI 512 to the output pads 622. Each of the first output lines OL1 and the second output lines OL2 may extend through the first metal layer and the second metal layer. For example, a first portion of each of the first output lines OL1 may be electrically connected to the first DDI 511 in the first metal layer and may be electrically connected to a second portion disposed in the second metal layer through a through hole CT41. For example, a first portion of each of the second output lines OL2 may be electrically connected to the second DDI 512 in the first metal layer and may be electrically connected to a second portion disposed in the second metal layer through a through hole CT42.

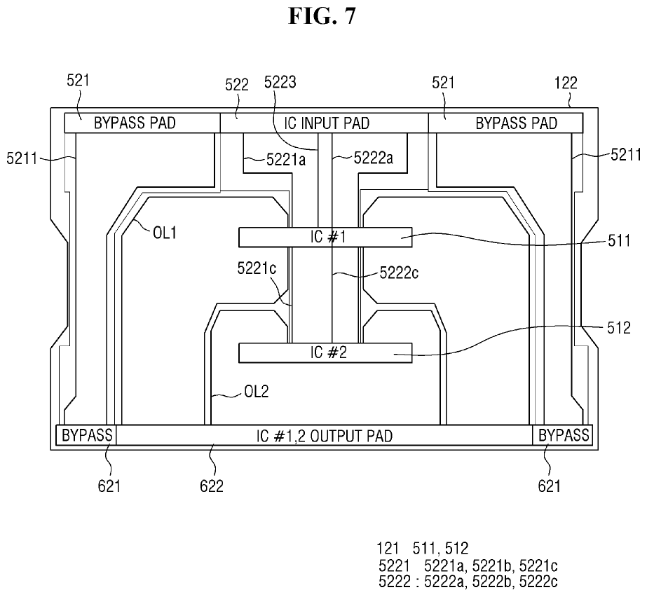

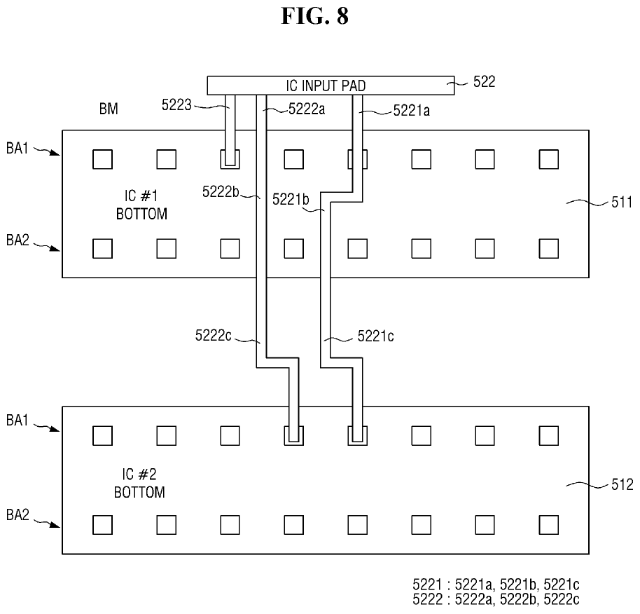

FIG. 7 is a layout view of a front portion of a flexible film 122 according to an embodiment. FIG. 8 is a schematic diagram illustrating a second independent line 5222 passing between bumps BM of a DDI according to an embodiment.

The embodiment of FIGS. 7 and 8 is different from the embodiment of FIGS. 5 and 6 in that the flexible film 122 includes a single metal layer. Therefore, only the features that are different from those of the embodiment of FIGS. 5 and 6 will be described below with reference to FIGS. 7 and 8.

Referring to FIGS. 7 and 8, the flexible film 122 according to the embodiment may have a single metal layer structure including a single metal layer. For example, each flexible film 122 may include a first metal layer adjacent to a front surface of the flexible film 122. The first metal layer may include lines for transmitting signals or power. For example, FIGS. 7 and 8 illustrate lines included in the first metal layer, and the illustrated lines may serve as lines for transmitting signals or power.

According to an embodiment, a first common line 5221a, a second common line 5221b, and a third common line 5221c may be disposed in the first metal layer. A first independent line 5223 and a second independent line 5222 may be disposed in the first metal layer. Bypass lines 5211 may be disposed in the first metal layer.

The first common line 5221a may be disposed between a first DDI 511 and an input pad 522 to connect the first DDI 511 and the input pad 522. For example, an end of the first common line 5221a may be electrically connected to the input pad 522, and another end of the first common line 5221a may be electrically connected to a bump BM of the first DDI 511 on the bottom of the first DDI 511. The second common line 5221b may pass under the first DDI 511. The second common line 5221b may extend from the bump BM of the first DDI 511, to which the first common line 5221a may be electrically connected, toward a second DDI 512. Here, the second common line 5221b may extend to pass between bumps BM disposed on the bottom of the first DDI 511. The third common line 5221c may be disposed between the first DDI 511 and the second DDI 512 to connect the second common line 5221b and the second DDI 512. For example, an end of the third common line 5221c may be electrically connected to the second common line 5221b, and another end of the third common line 5221c may be electrically connected to a bump BM of the second DDI 512.

In FIG. 8, BA1 represents a first bump array BA1 which refers to first bumps BM included in each of the first DDI 511 and the second DDI 512. BA2 represents a second bump array BA2 which refers to second bumps BM included in each of the first DDI 511 and the second DDI 512. As illustrated, the first bump array BA1 and the second bump array BA2 may be arranged parallel to each other. The first bump array BA1 may be disposed relatively closer to the input pad 522 than the second bump array BA2. The second bump array BA2 may be disposed relatively closer to an output pad 622 than the first bump array BA1.

Referring to FIG. 8, an end of the first common line 5221a may be electrically connected to the input pad 522, and another end of the first common line 5221a may be electrically connected to the first bump array BA1 on the bottom of the first DDI 511. The second common line 5221b may pass under the first DDI 511. The second common line 5221b may extend from a bump BM of the first DDI 511, to which the first common line 5221a may be electrically connected, toward the second DDI 512. Here, the second common line 5221b may extend to pass between the bumps BM of the second bump array BA2 of the first DDI 511.

The first independent line 5223 and the second independent line 5222 for independently transmitting signals or power to the first DDI 511 and the second DDI 512 may be arranged as follows. The first independent line 5223 may be disposed between the first DDI 511 and the input pad 522 to connect the first DDI 511 and the input pad 522 to each other. The second independent line 5222 may connect the second DDI 512 and the input pad 522 to each other via the bottom of the first DDI 511. For example, a first portion 5222a of the second independent line 5222 may be disposed between the first DDI 511 and the input pad 522, a second portion 5222b of the second independent line 5222 may pass between the bumps BM of the first DDI 511 on the bottom of the first DDI 511, and a third portion 5222c of the second independent line 5222 may be disposed between the first DDI 511 and the second DDI 512.

Referring to FIG. 8, the second independent line 5222 may extend to the second DDI 512 via the bottom of the first DDI 511. Here, the second independent line 5222 may pass between the bumps BM of the first bump array BA1 of the first DDI 511 and between the bumps BM of the second bump array BA2 of the first DDI 511.

According to a display device and a mobile electronic device including the same according to embodiments, it may be possible to readily secure a pad pitch while placing multiple integrated circuits on one flexible film, thereby increasing yield and reliability.

According to a display device and a mobile electronic device including the same according to embodiments, it may be possible to readily secure a pad pitch while placing multiple integrated circuits on one flexible film, thereby increasing yield and reliability.

However, the effects of the disclosure may not be restricted to the one set forth herein. The above and other effects of the disclosure will become more apparent to one of daily skill in the art to which the disclosure pertains by referencing the claims.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation.

What is claimed is:

1. A display device comprising:
a display panel;
a plurality of flexible films attached to a side of the display panel; and
a circuit board electrically connected to the display panel through the plurality of flexible films,
wherein each of the plurality of flexible films comprises:
a first display driver IC (DDI) and a second DDI spaced apart from each other on a surface of the flexible film;
a first common line electrically connecting an input pad and the first DDI;
a second common line branching from the first common line and extending under the first DDI to bypass the first DDI;
a third common line electrically connecting the second common line and the second DDI;
a first independent line electrically connecting the input pad and the first DDI; and
a second independent line electrically connecting the input pad and the second DDI.

2. The display device of claim 1, wherein
each of the plurality of flexible films comprises:
a first metal layer adjacent to a front surface of the flexible film, and
a second metal layer adjacent to a rear surface of the flexible film, and
the first DDI and the second DDI are disposed on the front surface of the flexible film.

3. The display device of claim 2, wherein in each of the plurality of flexible films
the input pad is disposed adjacent to a side of the flexible film and is disposed on the front surface of the flexible film,
an output pad is disposed adjacent to another side of the flexible film and is disposed on the rear surface of the flexible film, and
the first DDI is disposed between the input pad and the second DDI.

4. The display device of claim 3, wherein in each of the plurality of flexible films
the first common line and the third common line are disposed in the first metal layer, and
the second common line is disposed in the second metal layer.

5. The display device of claim 4, wherein in each of the plurality of flexible films, the first common line and the third common line are electrically connected through a plurality of through holes penetrating portions of the flexible film to connect the first metal layer and the second metal layer.

6. The display device of claim 5, wherein in each of the plurality of flexible films, the plurality of through holes comprise:
a first through hole in which the first common line and an end of the second common line are electrically connected; and
a second through hole in which the third common line and another end of the second common line are electrically connected.

7. The display device of claim 3, wherein in each of the plurality of flexible films, the first independent line is electrically connected to the first DDI through the first metal layer.

8. The display device of claim 3, wherein in each of the plurality of flexible films, the second independent line is electrically connected to the second DDI through the first metal layer and the second metal layer.

9. The display device of claim 1, wherein each of the plurality of flexible films comprises a plurality of bypass lines disposed on opposing front and rear surfaces of the flexible film to bypass the first DDI and the second DDI.

10. The display device of claim 1, wherein in each of the plurality of flexible films
the first DDI drives a plurality of first subpixels disposed in a first display area of the display panel,
the second DDI drives a plurality of second subpixels disposed in a second display area adjacent to the first display area, and
a circuit included in the first DDI and a circuit included in the second DDI are the same.

11. The display device of claim 1, wherein each of the plurality of flexible films comprises:
a first metal layer adjacent to a front surface of the flexible film, wherein
the first DDI and the second DDI are disposed on the front surface of the flexible film.

12. The display device of claim 11, wherein in each of the plurality of flexible films
the input pad is disposed adjacent to a side of the flexible film and is disposed on the front surface of the flexible film,
an output pad is disposed adjacent to another side of the flexible film and is disposed on a rear surface of the flexible film, and
the first DDI is disposed between the input pad and the second DDI.

13. The display device of claim 11, wherein the first through third common lines and the first and second independent lines in each of the plurality of flexible films are disposed in the first metal layer.

14. The display device of claim 13, wherein the second common line in each of the plurality of flexible films passes between a plurality of bumps of the first DDI attached to the front surface of the flexible film.

15. The display device of claim 13, wherein the second independent line in each of the plurality of flexible films passes between a plurality of bumps of the first DDI attached to the front surface of the flexible film.

16. A mobile electronic device comprising:
a display device that comprises:
a display panel;
a plurality of flexible films attached to a side of the display panel; and
a circuit board electrically connected to the display panel through the plurality of flexible films,
wherein each of the plurality of flexible films comprises:
a first DDI and a second DDI spaced apart from each other on a surface of the flexible film;
a first common line electrically connecting an input pad and the first DDI;
a second common line branching from the first common line and extending under the first DDI to bypass the first DDI;
a third common line electrically connecting the second common line and the second DDI;
a first independent line electrically connecting the input pad and the first DDI; and
a second independent line electrically connecting the input pad and the second DDI.

17. The mobile electronic device of claim 16, wherein
each of the plurality of flexible films comprises:
a first metal layer adjacent to a front surface of the flexible film, and
a second metal layer adjacent to a rear surface of the flexible film, and
the first DDI and the second DDI are disposed on the front surface of the flexible film.

18. The mobile electronic device of claim 17, wherein in each of the plurality of flexible films
the input pad is disposed adjacent to a side of the flexible film and is disposed on the front surface of the flexible film,
an output pad is disposed adjacent to another side of the flexible film and is disposed on the rear surface of the flexible film, and
the first DDI is disposed between the input pad and the second DDI.

19. The mobile electronic device of claim 18, wherein in each of the plurality of flexible films
the first common line and the third common line are disposed in the first metal layer, and
the second common line is disposed in the second metal layer.

20. The mobile electronic device of claim 19, wherein each of the plurality of flexible films are penetrated by a plurality of through holes in which the first common line and the third common line are electrically connected and in which the first metal layer and the second metal layer are electrically connected.
